(19) United States
(12) Patent Application Publication
(10) Pub. No.: US 2025/0153217 A1
(43) Pub. Date: May 15, 2025

(54) METHOD FOR FORMING THREE-DIMENSIONALLY SHAPED IMPACT ABSORPTION LAYER BY USING UV PARALLEL LIGHT IN MULTILAYERED LAMINATED STRUCTURE AND IMPACT ABSORPTION LAYER FORMED THEREBY

(71) Applicant: KYUNGPOOK NATIONAL UNIVERSITY INDUSTRY-ACADEMIC COOPERATION FOUNDATION, Daegu (KR)

(72) Inventor: Dong Yun LEE, Suwon-si (KR)

(73) Assignee: KYUNGPOOK NATIONAL UNIVERSITY INDUSTRY-ACADEMIC COOPERATION FOUNDATION, Daegu (KR)

(21) Appl. No.: 18/838,351

(22) PCT Filed: Feb. 15, 2023
(86) PCT No.: PCT/KR2023/002172

§ 371 Date: Nov. 22, 2024

(30) Foreign Application Priority Data
Feb. 15, 2022 (KR) 10-2022-0019359

(51) Int. Cl. B05D 3/06; B05D 1/32; G06F 1/16

(52) U.S. Cl. CPC B05D 3/067; B05D 1/32; G06F 1/1616

(57) ABSTRACT

The method of forming a three-dimensionally shaped impact absorption layer by using UV parallel light in a multi-layered laminated structure includes: (a) applying a composition for forming an impact absorption layer on top of a substrate; (b) forming a polymer layer on top of the composition; (c) placing a photomask on top of the polymer layer; (d) irradiating UV parallel light onto the photomask from two to eight directions at an angle greater than 0° and less than 90° with respect to a plane perpendicular to an exposure plane so that an impact absorption layer skeletal support is cured in parallel with the angle of the parallel light; and (e) removing the photomask and irradiating UV light having a lower intensity than that of the UV parallel light to form an impact-buffering portion around the skeletal support, thereby completing a three-dimensionally shaped impact absorption layer.

### TECHNICAL FIELD

The present invention relates to a method for forming a three-dimensionally shaped impact absorption layer by using UV parallel light in a multilayered laminated structure, and an impact absorption layer formed by the method. Specifically, the present invention relates to: a method for fabricating a multilayered laminated structure having improved impact resistance, restoring force, and elongation by irradiating parallel light and UV onto a photomask, and forming a three-dimensionally shaped impact absorption layer on the laminated structure using UV parallel light; an impact absorption layer formed by the method; and a device employing the impact absorption layer.

### BACKGROUND ART

Recently, as the society has entered the full-fledged information era, the display field, in which a large amount of information is processed and displayed, has developed rapidly, and in response, various flat display devices have been developed and are drawing attention. As displays have changed from flat forms to bendable and foldable forms, the existing cover window is changing from glass to a very thin form such as a thin film (colorless polyimide; CPI) or ultra-thin glass (UTG) for easy folding and unfolding.

Meanwhile, these flat panel displays use glass substrates to withstand the high-temperature heat generated during the manufacturing process, so there are limitations in making them lightweight, thin, and flexible.

Therefore, flexible display devices that are produced by using flexible materials such as plastics, instead of the existing inflexible glass substrates, to maintain the display performance even when curved like paper are rapidly emerging as next-generation flat panel display devices.

Flexible display devices employ plastic thin film transistor substrates instead of glass, and may be categorized into unbreakable devices, which have high durability, bendable devices, which can be bent without being broken, rollable devices, and foldable devices. These flexible display devices have advantages in space utilization, interior decoration, and design, and can have various applications.

However, since foldable displays must allow for folding and unfolding, the display panel, back plate, and cover window are all made of a very thin film. This thin film form vertically transmits most of the impacted transmitted from the outside. In other words, when an impact is applied from the outside to the cover window or back plate, since the cover window and back plate are made of a thin film, the impact applied from the outside is directly transmitted to the display panel positioned between the cover window and the back plate.

This ultimately causes damage to the display panel and reduces the display quality of the display panel.

### DETAILED DESCRIPTION OF THE INVENTION

### Technical Problem

To solve the above-described problems, one object of the present invention is to provide a method for forming a three-dimensionally shaped impact absorption layer by using UV parallel light to improve impact resistance, restoring force, and elongation.

In addition, another object of the present invention is to provide an impact absorption layer manufactured by the method for forming a three-dimensionally shaped impact absorption layer to improve the impact resistance, restoring force, and elongation of displays.

### Technical Solution

To achieve the object, the present invention provides a method for forming a three-dimensionally shaped impact absorption layer using UV parallel light in a multilayered laminated structure, including:
(a) applying a composition for forming an impact absorption layer on top of a substrate;
(b) forming a polymer layer on top of the composition;
(c) placing a photomask on top of the polymer layer;
(d) irradiating UV parallel light onto the photomask from two to eight directions at an angle greater than 0° and less than 90° with respect to a plane perpendicular to an exposure plane so that an impact absorption layer skeletal support is cured in parallel with the angle of the parallel light; and
(e) removing the photomask and irradiating UV light having a lower intensity than that of the UV parallel light to form an impact-buffering portion around the skeletal support, thereby completing a three-dimensionally shaped impact absorption layer.

To achieve the other object, the present invention provides a method for forming a three-dimensionally shaped impact absorption layer using UV parallel light in a multilayered laminated structure, including:
(a) applying a composition for forming an impact absorption layer on a substrate;
(b) forming a polymer layer on top of the composition;
(c) placing a half-cut mask on top of the polymer layer; and
(d) irradiating UV parallel light onto the half-cut mask from two to eight directions at an angle greater than 0° and less than 90° with respect to a plane perpendicular to an exposure plane so that an impact absorption layer skeletal support is cured by the UV parallel light passing through a hole of the half-cut mask in parallel with the angle of the parallel light, and the UV parallel light passing through a portion other than the hole of the half-cut mask forms an impact-buffering portion around the skeletal support, thereby completing a three-dimensionally shaped impact absorption layer.

To achieve the other object, the present invention provides a three-dimensionally shaped impact absorption layer manufactured by the manufacturing method.

To achieve the other object, the present invention provides a device employing a laminated structure including the three-dimensionally shaped impact absorption layer.

### Advantageous Effects

The three-dimensionally shaped impact absorption layer according to the manufacturing method of the present invention consists of an impact absorption layer skeletal support and an impact-buffering portion around the skeletal support, each of which has a different modulus value. Since the skeletal support maintains a high hardness of the structure and the impact-buffering portion disperses internal/external impacts, a three-dimensionally shaped impact absorption layer with excellent impact resistance, restoring force, and elongation can be manufactured. The impact absorption layer can be used in a laminated structure and can also be utilized in a device employing this laminated structure.

### DESCRIPTION OF THE DRAWINGS

FIG. 1 shows images of (a) a triangular prism structure, (b) a cone array, (c) a triangular structure, and (d) a pyramid structure formed according to the angle of parallel light irradiation according to one embodiment of the present invention.

FIG. 2 shows images illustrating photomask patterns according to one embodiment of the present invention, the images illustrating a square pattern (a) and a triangular pattern (b).

FIG. 3 shows a schematic image illustrating a method for manufacturing an impact layer of a three-dimensional thin film sandwich structure formed through parallel light photometry according to an embodiment of the present invention.

FIG. 4 shows a graph illustrating the stress-strain curve according to the usage time of a curing agent trimethylolpropane triacrylate (TMPTA) when only parallel light was irradiated according to an embodiment of the present invention.

FIG. 5 shows a graph illustrating the modulus of an impact absorption layer measured when only parallel light was irradiated according to one embodiment of the present invention.

FIG. 6 shows a graph illustrating the stress-strain curve when a photomask was not used during parallel light and UV irradiation according to one embodiment of the present invention.

FIG. 7 shows a graph illustrating the modulus measured over time when a photomask was not used during parallel light and UV irradiation according to one embodiment of the present invention.

FIG. 8 shows a graph illustrating the stress-strain curve when only full UV was irradiated without a photomask according to one embodiment of the present invention.

FIG. 9 shows a graph illustrating the modulus of a composition for forming an impact absorption layer when only full UV was irradiated without a photomask according to one embodiment of the present invention.

FIG. 10 shows a graph illustrating the stress-strain curve when parallel light was irradiated onto a photomask and then UV was irradiated according to one embodiment of the present invention.

FIG. 11 shows a graph illustrating the modulus of an impact absorption layer measured when parallel light was irradiated onto a photomask and then UV was irradiated according to one embodiment of the present invention.

### MODES OF THE INVENTION

Hereinafter, the present invention will be described in more detail.

One aspect of the present invention provides a method for forming a three-dimensionally shaped impact absorption layer using UV parallel light in a multilayered laminated structure, including: (a) applying a composition for forming an impact absorption layer on top of a substrate; (b) forming a polymer layer on top of the composition; (c) placing a photomask on top of the polymer layer; (d) irradiating UV parallel light onto the photomask from two to eight directions at an angle greater than 0° and less than 90° with respect to a plane perpendicular to an exposure plane so that an impact absorption layer skeletal support is cured in parallel with the angle of the parallel light; and (e) removing the photomask and irradiating UV light having a lower intensity than that of the UV parallel light to form an impact-buffering portion around the skeletal support, thereby completing a three-dimensionally shaped impact absorption layer.

In the present invention, a three-dimensionally shaped impact absorption layer may be formed through two operations including an exposure operation using a photomask and an exposure operation after removing the same. Specifically, the impact absorption layer of the present invention consists of an impact absorption layer skeletal support and an impact-buffering portion around the skeletal support. The ‘skeletal support’ refers to a portion where UV parallel light is transmitted and thus a curing composition of the impact absorption layer is cured at the same angle and in the same shape as the parallel light. Therefore, it may be considered that the structure and shape of a skeletal support implement the shape, size, and spacing of photomask holes as they are.

The impact absorption layer is formed as two separate portions, which are a skeletal support and an impact-buffering portion, and while having different hardness, the portions may maximize impact absorption within the multilayered laminated structure. In the process of forming the skeletal support and the impact-buffering portion, various types of UV and photomasks are selected and used.

By introducing a composition for forming an impact absorption layer between a substrate and a polymer by irradiating UV parallel light and thus forming a three-dimensional shape, a skeletal support, which is a cured structure, may be formed in parallel with the angle of the UV parallel light. In the impact absorption layer, UV light having a lower intensity than that of UV parallel light may be irradiated onto a remaining area other than the skeletal support formed by the UV parallel light in order to form an impact-buffering portion.

Herein, the term “UV light having a lower intensity than that of UV parallel light” refers to UV light having an intensity lower than that of UV parallel light during the operations of removing the photomask and performing exposure. An impact-buffering portion formed around a cured impact absorption layer skeletal support may be formed as a cured structure having relatively low hardness due to the UV light having an intensity lower than that of UV parallel light. The portion formed in this manner will be referred to as an “impact-buffering portion” herein. Since an impact absorption layer includes an impact absorption layer skeletal support and an impact-buffering portion, the impact-buffering portion may be referred to as a peripheral portion surrounding the skeletal support. The structure cured by the UV parallel light is hard and thus increases durability, and the impact-buffering portion of the remaining portion excluding the cured structure disperses impact and thus serves to increase impact resistance, restoring force, and elongation.

UV parallel light may be irradiated onto the photomask in two to eight directions, preferably two to six directions, and more preferably two to four directions. In addition, UV parallel light may be irradiated at an angle greater than 0° and less than 90°, and preferably at an angle of 10° to 80°, with respect to a plane perpendicular to an exposure plane. Depending on the angle at which UV parallel light is irradiated, the skeletal support in an impact absorption layer formed on a substrate may be manufactured in various shapes.

In other words, the cross-sectional shape of a hole of a photomask may have various shapes such as a circle, an ellipse, a straight line, a curve, or a surface. In addition, the size of the mask hole, the spacing between the holes, and the depth of the holes may also be changed in various ways. Since the degree of exposure and curing is different depending on the shape, spacing, and depth of the mask holes, the physical properties of an impact absorption layer may be changed, and when forming and using an impact absorption layer in this manner, the cross-sectional shape, spacing, and depth (thickness) of the holes may be designed in consideration of the impact absorption strength.

The shape of the skeletal support of an impact absorption layer is preferably formed into various shapes such as a sandwich panel, a pyramidal structure, or a cone array depending on the angle of the parallel light, but the shape is not limited thereto. Various shapes are all possible depending on the cross-sectional shape, size, spacing, depth of the mask holes, the intensity of the UV parallel light, and the irradiation angle of the UV parallel light.

An impact absorption layer may be used for various purposes, and for example, it may be used as a 3D adhesive with a three-dimensional shape by using an adhesive component.

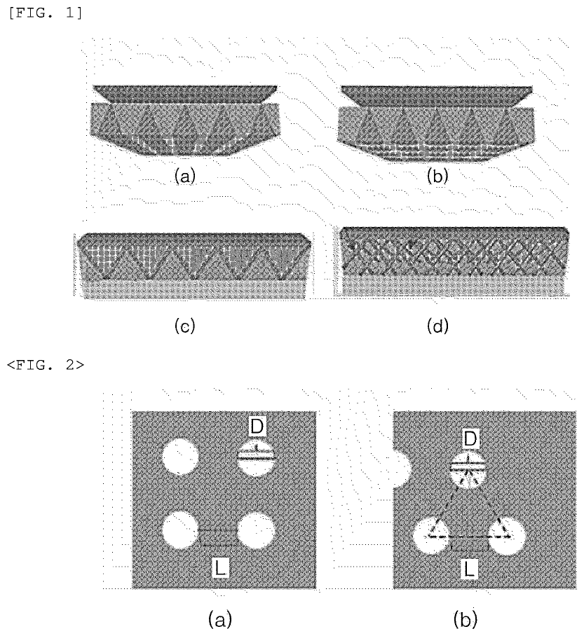

FIG. 1 shows images of (a) a triangular prism structure, (b) a cone array, (c) a triangular structure, and (d) a pyramid structure formed according to the angle of parallel light irradiation according to one embodiment of the present invention. Referring to FIG. 1, various patterns may be formed by changing the shape of the photomask or the shape of the hole.

In addition, even when UV parallel light is irradiated, each modulus varies depending on the curing time, and when the parallel light irradiation time is long, complete cross-linking occurs and the modulus increases, so a specific shape or structure is exhibited as shown in FIG. 1. On the other hand, when the parallel light irradiation time is short or parallel light is not irradiated, curing may occur partially and an impact-buffering portion with a small modulus may be formed.

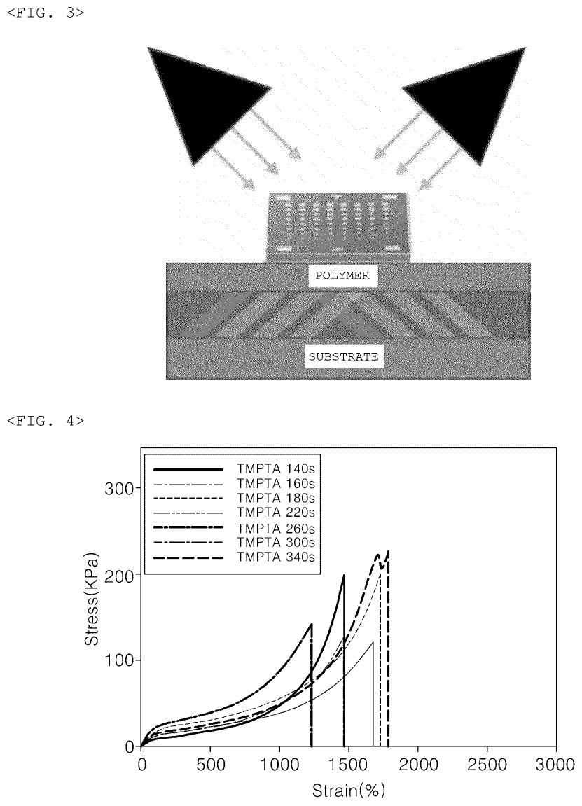

FIG. 2 shows images illustrating photomask patterns according to one embodiment of the present invention, the images illustrating a square pattern (a) and a triangular pattern (b). Referring to FIG. 2, D represents the diameter of the photomask holes, and L represents the spacing between the photomask holes. In FIG. 2, (a) shows that four holes of the photomask form a square, and (b) shows a case where the spacing of L connected from the center points of the holes is all the same. However, the present invention is not limited thereto, and the shape of the photomask may be modified and used in various ways, such as when D and L are the same spacing, when the spacing of L is changed, and when the pattern of the photomask holes is changed. Regardless of the shape or size of the photomask, or the size and spacing of the holes, a structure (skeletal support) having a high modulus may be formed in parallel with the light of parallel light passing through the photomask holes, and an impact-buffering portion may be formed in the other portion.

The modulus of an impact absorption layer is preferably 0.1 to 1 kPa, more preferably 0.3 to 1 kPa. The modulus of an impact absorption layer skeletal support forming an impact absorption layer is preferably 0.15 to 0.4 kPa, more preferably 0.2 to 0.35 kPa. The modulus of an impact absorption layer is preferably 0.10 to 0.30 kPa by forming an impact-buffering portion around the skeletal support forming the impact absorption layer.

For a polymer layer on top of a composition for forming an impact absorption layer, the type of polymer is not limited, but polyethylene terephthalate (PET) is preferable. The polymer itself may be used as a polymer layer, but it is preferred to apply it after corona treatment. The thickness of a polymer layer is preferably 30 to 100 μm, and more preferably 30 to 50 μm.

Another aspect of the present invention provides a method for forming a three-dimensionally shaped impact absorption light in a multilayered laminated layer using UV parallel structure, including: (a) applying a composition for forming an impact absorption layer on a substrate; (b) forming a polymer layer on top of the composition; (c) placing a half-cut mask on top of the polymer layer; and (d) irradiating UV parallel light onto the half-cut mask from two to eight directions at an angle greater than 0° and less than 90° with respect to a plane perpendicular to an exposure plane so that an impact absorption layer skeletal support is cured by the UV parallel light passing through a hole of the half-cut mask in parallel with the angle of the parallel light, and the UV parallel light passing through a portion other than the hole of the half-cut mask forms an impact-buffering portion around the skeletal support, thereby completing a three-dimensionally shaped impact absorption layer.

In another embodiment of the present invention, the two operations of using and removing a photomask may be shortened to a single operation to form a three-dimensionally shaped impact absorption layer. In this operation, in addition to a photomask, which is a general pattern mask, a pattern mask whose UV light transmittance is adjusted to an appropriate degree, not 100% or 0% in an on-off mode, may be used, and this is referred to by the term “half-cut mask.”

Unlike a photomask, when UV parallel light is irradiated onto a half-cut mask, strong UV parallel light is 100% transmitted through the holes of the half-cut mask to form an impact absorption layer support, but UV parallel light may not be completely transmitted but may only be partially transmitted through areas other than the holes of the mask. Therefore, in a single exposure, the area where UV parallel light is 100% transmitted (the holes of the half-cut mask) forms a skeletal support, and the area where it is transmitted less than 100% (areas other than the holes of the half-cut mask) forms an impact-buffering portion, so that the manufacturing process may be shortened compared to a general photomask. At this time, the transmittance of the areas other than the holes of the half-cut mask may be appropriately adjusted in consideration of the degree of curing of the impact-buffering portion.

The curing speed of the composition for forming an impact absorption layer becomes faster as the intensity of the parallel UV light and the concentration of the initiator increase, so the curing speed may be adjusted by adjusting the intensity of the parallel light or the concentration of the initiator.

Still another aspect of the present invention provides a three-dimensionally shaped impact absorption layer manufactured by the manufacturing method.

The composition for forming an impact absorption layer may include a polymer and/or copolymer, a photoinitiator, and a curing agent.

As the polymer, for example, as the copolymer, a polystyrene-polymethylmethacrylate copolymer, a polybutadiene-polybutylmethacrylate copolymer, a polybutadiene-polydimethylsiloxane copolymer, a polybutadiene-polymethylmethacrylate copolymer, a polybutadiene-polyvinylpyridine copolymer, polybutylacrylate-polymethylmethacrylate, polybutylacrylate-polyvinylpyridine, polyisoprene-polyvinylpyridine, polyisoprene-polymethylmethacrylate, polyhexylacrylate-polyvinylpyridine, polyisobutylene-polybutylmethacrylate, polyisobutylene-polymethylmethacrylate, polyisobutylene-polybutylmethacrylate, polyisobutylene-polydimethylsiloxane, polybutylmethacrylate-polybutylacrylate, polyethylethylene-polymethylmethacrylate, polystyrene-polybutylmethacrylate, polystyrene-polybutadiene, polystyrene-polyisoprene, polystyrene-polydimethylsiloxane, polystyrene-polyvinylpyridine, polyethylethylene-polyvinylpyridine, polyethylene-polyvinylpyridine, polyvinylpyridine-polymethylmethacrylate, polyethyleneoxide-polyisoprene, polyethyleneoxide-polybutadiene, polyethyleneoxide-polystyrene, polyethyleneoxide-polymethylmethacrylate, polyethyleneoxide-polydimethylsiloxane, polystyrene-polyethyleneoxide, and the like may be used.

The photoinitiator may preferably be one or more selected from the group consisting of benzyldimethyl ketal (Irgacure #651), 2-methyl-1 [4-(methythio)phenyl]-2-morpholino-propan-1-on (Irgacure #907), α,α-methoxy-α-hydroxyacetophenone (Irgacure #651), and 2-hydroxy-2-methyl-1-phenyl-propan-1-one (Irgacure #1173).

The solvent of a composition for forming an impact absorption layer is not particularly limited. As examples of suitable solvents, ethylene glycol monomethyl ethyl, ethylene glycol monoethyl ether, ethylene glycol monomethyl ether, ethylene glycol monoacetate, diethylene glycol, diethylene glycol monomethyl ether acetate, monoethyl ether, propylene glycol propylene glycol, propylene glycol monoacetate, toluene, xylene, methyl ethyl ketone, methyl isoamyl ketone, cyclohexanone, dioxane, methyl lactate, ethyl lactate, methyl pyruvate, ethyl pyruvate, methyl methoxypropionate, ethyl ethoxy propionate, N, N-dimethylformamide, N, N-dimethylacetamide, N-methyl 2-pyrrolidone, 3-ethoxyethyl propionate, 2-heptanone, gamma-butyrolactone, 2-hydroxypropionethyl, ethyl 2-hydroxy-2-methylpropionate, ethyl ethoxyacetate, ethyl hydroxyacetate, methyl 2-hydroxy 3-methylbutanoate, methyl 3-methoxy 2-methylpropionate, ethyl 3-ethoxypropionate, ethyl 3-methoxy 2-methylpropionate, 4-methyl-2-pentanol, 4-methyl-2-pentyl acetate, isopropanol, methyl alcohol, ethyl alcohol, normal butyl alcohol, cyclopentanol, cyclopentanone, ethyl acetate, butyl acetate, and the like may be used alone or as a mixture thereof.

The composition for forming an impact absorption layer of the present invention may further include additives such as a surfactant. As the surfactant, any surfactant used in this technical field, such as a fluorinated surfactant, an anionic surfactant, a cationic surfactant, or a nonionic surfactant, may be used without any particular limitation.

Yet another aspect of the present invention provides a device employing a laminated structure including the three-dimensionally shaped impact absorption layer. The device is also applicable to display panels, and for example, devices for foldable, rollable, and flat-panel displays, such as organic light-emitting diode (OLED), may all be included.

The impact absorption layer of the present invention can increase the durability of the device by including both a skeletal support and an impact-buffering portion around the skeletal support, and since it has improved impact resistance, restoring force, and elongation, it is strongly resistant to internal and external impacts, and thus can be utilized in other applications such as a display protection film, various packaging materials, furniture protection materials, and a protective film for electronic devices.

Herein, when a portion is said to “comprise” a certain element, it means that other elements may be further included rather than excluding other elements, unless otherwise specified. In addition, the terminology used herein is for the purpose of describing embodiments and is not intended to limit the present invention. Singular expressions include plural expressions unless the context clearly dictates otherwise.

Herein, the expressions “A or B,” “at least one of A and/or B,” or “one or more of A or/and B” may include all possible combinations of the items listed together. For example, “A or B,” “at least one of A and B,” or “at least one of A or B” may all refer to cases where (1) at least one A is included, (2) at least one B is included, or (3) both at least one A and at least one B are included.

Hereinafter, the present invention will be described in more detail with preferred examples. However, it will be obvious to those skilled in the art that these examples are intended to explain the present invention more specifically and that the scope of the present invention is not limited thereby.

### EXAMPLES

### Example 1

The adhesive included 30 g of Irgacure 980, 9 g of isobornyl acrylate (IBOA), 0.3 g of acetic acid (AA), and 0.4 g of Irgacure 651, and 0.04 g of 1,6-hexanediol diacrylate (HDDA) or 0.04 g of trimethylolpropane triacrylate (TMPTA) was used as a curing agent. The adhesive was applied in a thickness of 1 mm. It was confirmed how the cured shape changed depending on the film thickness and UV irradiation time. In the case of the cured shape (3D pattern), ethyl acetate (EAC) or toluene, which is capable of dissolving uncross-linked adhesive after curing, was used as a solvent, and the adhesive was washed out and removed using the solvent to confirm the pattern shape. A photomask with a hole diameter of 800 μm and a hole spacing of 1200 μm was used.

### Example 2—Parallel Light Irradiation Experiment

An experiment was performed by varying the UV irradiation amount and time, photoinitiator, and curing agent due to multidirectional irradiation. To fabricate a 3D pattern, an experiment was performed to implement a pattern by irradiating in one direction, two directions, and four directions through 45-degree photometry. As the number of irradiation directions increases, UV is received redundantly, so the UV irradiation amount and time must be adjusted accordingly, and the type and content of the photoinitiator and hardener must be adjusted accordingly.

### <Results and Evaluation>

### Results Obtained by Irradiating Parallel Light Only

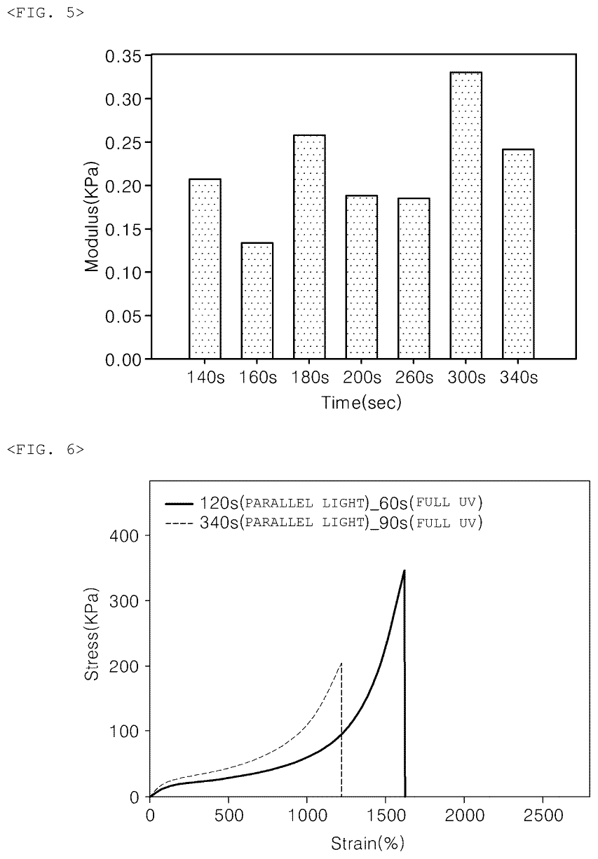

FIG. 4 shows a graph illustrating the stress-strain curve according to the usage time of a curing agent TMPTA when only parallel light was irradiated according to an embodiment of the present invention.

Referring to FIG. 4, only parallel light was irradiated without a photomask, and no full UV irradiation was performed thereafter to manufacture the impact absorption layer. The stress-strain curve was confirmed at the time of 140, 160, 180, 220, 260, 300, and 340 seconds. Since the maximum irradiation time of the parallel light machine was 340 seconds, irradiation for more than 340 seconds could not be performed. When the structure was fabricated using a photomask, the structure was best fabricated when the parallel light was irradiated for 130 seconds.

FIG. 5 shows a graph illustrating the modulus of a impact absorption layer (adhesive) measured when only parallel light was irradiated according to one embodiment of the present invention.

TABLE 1

| | 140 s | 160 s | 180 s | 220 s | 260 s | 300 s | 340 s |
|---|---|---|---|---|---|---|---|
| Mod- | 0.20679 | 0.13194 | 0.25908 | 0.18922 | 0.18423 | 0.32934 | 0.24072 |
| ulus | | | | | | | |
| (KPa) | | | | | | | |

Referring to FIG. 5 and Table 1, the modulus of the impact absorption layer was highest at 300 seconds when only parallel light was irradiated and no photomask was used and no UV irradiation was performed.

### Parallel Light and Full UV Irradiation

Parallel light was irradiated without a photomask, and then full UV was irradiated.

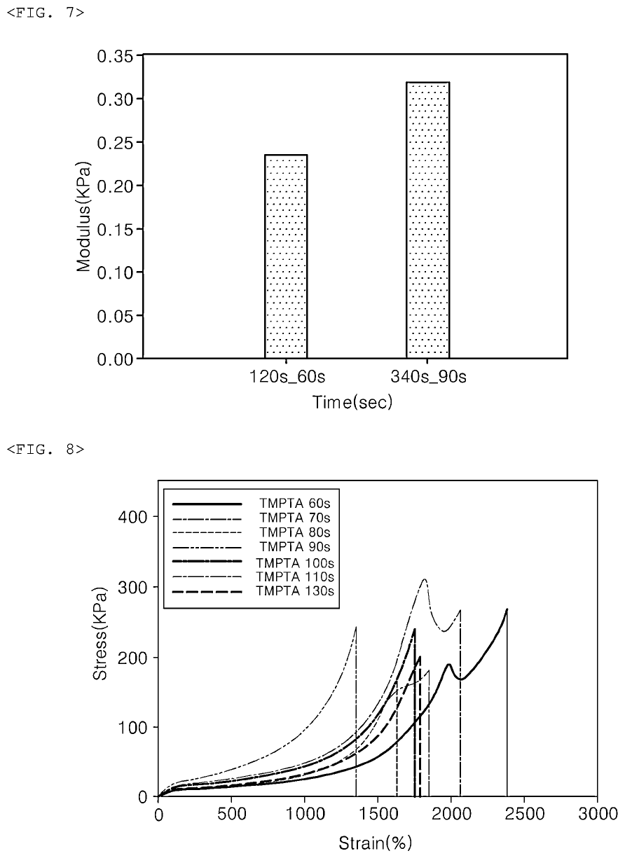

FIG. 6 shows a graph illustrating the stress-strain curve when a photomask was not used during parallel light and UV irradiation according to one embodiment of the present invention

FIG. 7 shows a graph illustrating the modulus measured over time when a photomask was not used during parallel light and UV irradiation according to one embodiment of the present invention. The numerical values are shown in Table 2 below.

TABLE 2

| | 120 s_60 s | 340 s_90 s |
|---|---|---|
| Modulus (KPa) | 0.234531 | 0.317365 |

Each of the time shown in FIG. 7 and Table 2 represents the ‘parallel light irradiation time full UV irradiation time.’ Parallel light was irradiated without a photomask to form a pyramidal structure, and UV was irradiated to form impact-buffering portion in the area where the pyramidal structure was not formed. The modulus value was the lowest when parallel light was irradiated for 120 seconds, which was right before the structure was formed the best, and then full UV was irradiated for 60 seconds. The modulus value was the highest when parallel light was irradiated for 340 seconds, which was the maximum irradiation time, and then full UV was irradiated for 90 seconds.

Full UV Irradiation without Parallel Light

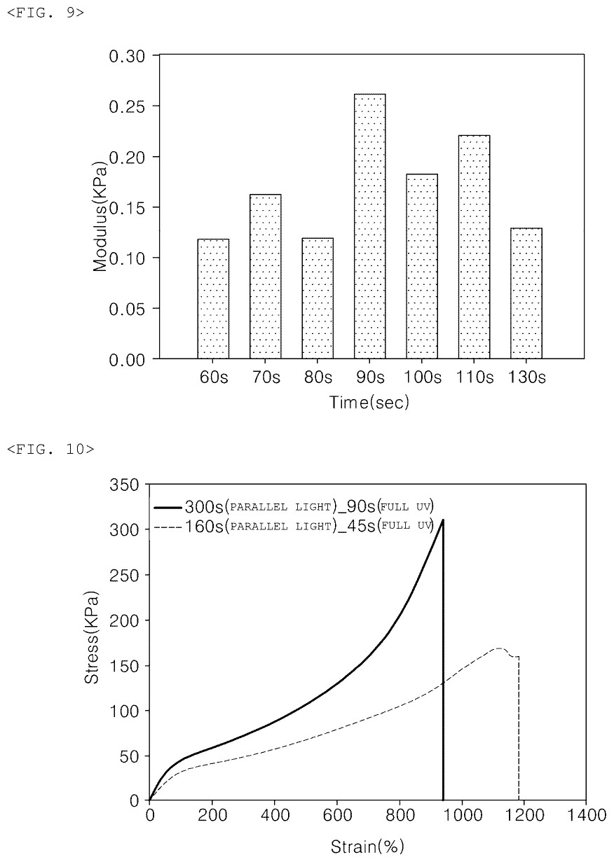

FIG. 8 shows a graph illustrating the stress-strain curve when only full UV was irradiated without a photomask according to one embodiment of the present invention

FIG. 9 shows a graph illustrating the modulus of a composition for forming a impact absorption layer when only full UV was irradiated without a photomask according to one embodiment of the present invention. The numerical values are shown in Table 3 below.

TABLE 3

| | 60 s | 70 s | 80 s | 90 s | 100 s | 110 s | 130 s |
|---|---|---|---|---|---|---|---|
| Mod- | 0.11776 | 0.16268 | 0.11776 | 0.26507 | 0.18423 | 0.22036 | 0.12894 |
| ulus | | | | | | | |
| (KPa) | | | | | | | |

Referring to FIG. 8, FIG. 9, and Table 3, full UV was irradiated for 60 seconds, 70 seconds, 80 seconds, 90 seconds, 100 seconds, 110 seconds, and 130 seconds, respectively, without a photomask, and parallel light irradiation was not performed at that time. The minimum time for the prepared adhesive to not smear the hand was approximately 45 to 50 seconds. Therefore, the experiment was performed from after 60 seconds. Since the modulus value was the highest when the irradiation was performed for 90 seconds, it was determined that performing the experiment under longer time conditions was not very meaningful.

### Parallel Light and Full UV Irradiation on Photomask

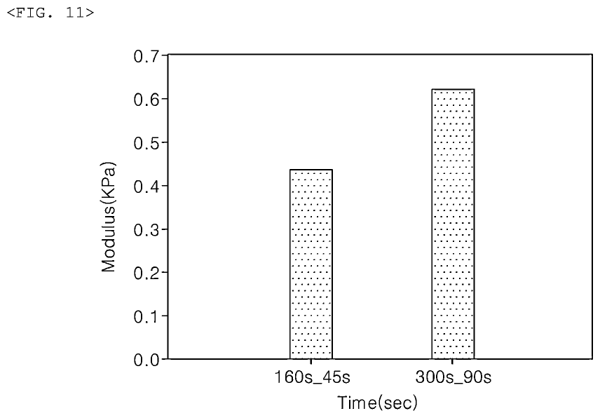

FIG. 10 shows a graph illustrating the stress-strain curve when parallel light was irradiated onto a photomask and then UV was irradiated according to one embodiment of the present invention.

FIG. 11 shows a graph illustrating the modulus of an impact absorption layer measured when parallel light was irradiated onto a photomask and then UV was irradiated according to one embodiment of the present invention.

TABLE 4

| | 300 s_90 s | 160 s_45 s |
|---|---|---|
| Modulus (KPa) | 0.613772 | 0.430539 |

Referring to FIG. 10, FIG. 11, and Table 4, the graph shows the results obtained after 300 seconds of parallel light irradiation using a photomask and 90 seconds of full UV irradiation followed by 160 seconds of parallel light irradiation using a photo mask and 45 seconds of full UV irradiation. Through the above experiment, the conditions with the highest modulus and the conditions with the lowest modulus were combined to measure the values with the highest modulus and the lowest modulus when forming a structure.

It was confirmed that in the case where a photomask was used and both parallel light and UV were irradiated, the highest modulus was formed when parallel light was irradiated for 300 seconds and then UV was irradiated for 90 seconds.

In summary, it was discovered that a 3D structure spring was formed according to the size and spacing of the photomask holes, that a 3D structure spring was formed by irradiating parallel light on the polymer and curing it, and that a 3D structure spring was formed according to the irradiation time of the parallel light. It was confirmed that the spacing, size, and pattern of the holes formed in the 3D structure impact absorption layer may also be changed.

The foregoing has broadly described the features and technical advantages of the present invention so that the scope of the claims that will be described later may be better understood. Those skilled in the art will understand that the present invention may be implemented in other specific forms without changing the technical idea or essential features thereof. Therefore, it should be understood that the above-described embodiments are exemplary in all respects and not restrictive. The scope of the present invention is indicated by the claims described below rather than the above detailed description, and all changed or modified forms derived from the claims and their equivalents should be construed as being included in the scope of the present invention.

1. A method for forming a three-dimensionally shaped impact absorption layer using UV parallel light in a multilayered laminated structure, comprising:
(a) applying a composition for forming an impact absorption layer on top of a substrate;
(b) forming a polymer layer on top of the composition;
(c) placing a photomask on top of the polymer layer;
(d) irradiating UV parallel light onto the photomask from two to eight directions at an angle greater than 0° and less than 90° with respect to a plane perpendicular to an exposure plane so that an impact absorption layer skeletal support is cured in parallel with the angle of the parallel light; and
(e) removing the photomask and irradiating UV light having a lower intensity than that of the UV parallel light to form an impact-buffering portion around the skeletal support, thereby completing a three-dimensionally shaped impact absorption layer.

2. A method for forming a three-dimensionally shaped impact absorption layer using UV parallel light in a multilayered laminated structure, comprising:
(a) applying a composition for forming an impact absorption layer on a substrate;
(b) forming a polymer layer on top of the composition;
(c) placing a half-cut mask on top of the polymer layer; and
(d) irradiating UV parallel light onto the half-cut mask from two to eight directions at an angle greater than 0° and less than 90° with respect to a plane perpendicular to an exposure plane so that an impact absorption layer skeletal support is cured by the UV parallel light passing through a hole of the half-cut mask in parallel with the angle of the parallel light, and the UV parallel light passing through a portion other than the hole of the half-cut mask forms an impact-buffering portion around the skeletal support, thereby completing a three-dimensionally shaped impact absorption layer.

3. A three-dimensionally shaped impact absorption layer manufactured by the method according to claim 1.

4. The three-dimensionally shaped impact absorption layer of claim 3, wherein the impact absorption layer skeletal support is one or more selected from a sandwich panel, a pyramidal structure, and a cone structure.

5. A device employing a laminated structure including the three-dimensionally shaped impact absorption layer of claim 3.

6. A three-dimensionally shaped impact absorption layer manufactured by the method according to claim 2.

7. The three-dimensionally shaped impact absorption layer of claim 6, wherein the impact absorption layer skeletal support is one or more selected from a sandwich panel, a pyramidal structure, and a cone structure.

8. A device employing a laminated structure including the three-dimensionally shaped impact absorption layer of claim 6.
